(19) United States
(12) Patent Application Publication
(10) Pub. No.: US 2024/0063091 A1
(43) Pub. Date: Feb. 22, 2024

(54) THERMALLY ENHANCED STRUCTURAL MEMBER AND/OR BOND LAYER FOR MULTICHIP COMPOSITE DEVICES

(71) Applicant: Intel Corporation, Santa Clara, CA (US)

(72) Inventors: Adel Elsherbini, Chandler, AZ (US); Feras Eid, Chandler, AZ (US); Scot Kellar, Bend, OR (US); Yoshihiro Tomita, Tsukuba-shi (JP); Rajiv Mongia, Portland, OR (US); Kimin Jun, Portland, OR (US); Shawna Liff, Scottsdale, AZ (US); Wenhao Li, Chandler, AZ (US); Johanna Swan, Scottsdale, AZ (US); Bhaskar Jyoti Krishnatreya, Hillsboro, OR (US); Debendra Mallik, Chandler, AZ (US); Krishna Vasanth Valavala, Chandler, AZ (US); Lei Jiang, Camas, WA (US); Xavier Brun, Hillsboro, OR (US); Mohammad Enamul Kabir, Portland, OR (US); Haris Khan Niazi, Scottsdale, AZ (US); Jiraporn Seangatith, Chandler, AZ (US); Thomas Sounart, Chandler, AZ (US)

(73) Assignee: Intel Corporation, Santa Clara, CA (US)

(21) Appl. No.: 17/891,735

(22) Filed: Aug. 19, 2022

(51) Int. Cl. H01L 23/473; H01L 23/00; H01L 25/065; H01L 23/367; H01L 23/373

(52) U.S. Cl. CPC H01L 23/473; H01L 24/08; H01L 25/0652; H01L 24/16; H01L 24/32; H01L 24/73; H01L 23/3677; H01L 23/3675; H01L 23/3732; H01L 23/3738; H01L 2924/3511; H01L 2224/08145; H01L 2224/08121; H01L 2224/16225; H01L 2224/32225; H01L 2224/73204; H01L 2924/182; H01L 2924/186

(57) ABSTRACT

Microelectronic devices, assemblies, and systems include a multichip composite device having one or more chiplets bonded to a base die and an inorganic dielectric material adjacent the chiplets and over the base die. The multichip composite device is coupled to a structural member that is made of or includes a heat conducting material, or has integrated fluidic cooling channels to conduct heat from the chiplets and the base die.

### BACKGROUND

As computing devices continue to get smaller and more powerful, thermal management presents new challenges. In particular, thermal management of multichip composite devices including a number of 3D stacked dies in a composite structure faces a number of challenges. Current architectures may include a handle die made of silicon that is bonded to active dies using a dielectric layer. When the active dies, including chiplets, have high power densities, the heat spreading provided by the silicon handle die may be insufficient to prevent the temperatures from exceeding a threshold value, causing damage to the device or requiring throttling (reducing power), which negatively impacts performance. Therefore, there is a need to more efficiently remove heat from the active dies of multichip composite devices.

It is with respect to these and other considerations that the present improvements have been needed. Such improvements may become critical as the desire to improve computing device performance and the corresponding necessity to remove heat from such devices becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a cross-sectional side view of a microelectronic device including a handle die side heat removal layer;

FIG. 1B illustrates a cross-sectional plan view of the microelectronic device of FIG. 1A;

FIGS. 1C and 1D illustrate cross-sectional side views of device structures as process operations are performed to fabricate the microelectronic device of FIGS. 1A and 1B;

FIG. 2A illustrates a cross-sectional side view of a microelectronic device including a high thermal conductivity handle layer or die;

FIGS. 2B and 2C illustrate cross-sectional side views of device structures as process operations are performed to fabricate the microelectronic device of FIG. 1A;

FIG. 3A illustrates a cross-sectional side view of a microelectronic device including a high thermal conductivity handle die including through vias;

FIG. 3B illustrates a cross-sectional side view of a microelectronic device including a high thermal conductivity handle die including through vias of differing sizes and densities;

FIGS. 3C, 3D, and 3E illustrate cross-sectional side views of device structures as process operations are performed to fabricate the microelectronic devices of FIGS. 3A and 3B;

FIG. 4A illustrates a cross-sectional side view of a microelectronic device incorporating integrated lateral fluidic cooling;

FIG. 4B illustrates a cross-sectional plan view of the microelectronic device of FIG. 4A;

FIGS. 4C, 4D, and 4E illustrate cross-sectional side views of device structures as process operations are performed to fabricate the microelectronic device of FIGS. 4A and 4B;

FIG. 5 illustrates a cross-sectional side view of a microelectronic device incorporating integrated perpendicular fluidic cooling;

FIG. 6A illustrates a cross-sectional side view of a handle die having a multilayer structure for integration of perpendicular fluidic cooling;

FIG. 6B illustrates a cross-sectional plan view of the handle die of FIG. 6A;

FIG. 7 illustrates a cross-sectional side view of a microelectronic device incorporating integrated perpendicular fluidic cooling with a central fluid inlet port and peripheral fluid outlet ports;

FIG. 8 illustrates a cross-sectional side view of a microelectronic device incorporating integrated perpendicular fluidic cooling with a central fluid outlet port and peripheral fluid inlet ports;

FIG. 9 illustrates a cross-sectional side view of a microelectronic device incorporating integrated perpendicular fluidic cooling having a fluid manifold off-die;

FIG. 10A illustrates a cross-sectional side view of a microelectronic device including an enhanced thermal bonding layer;

FIGS. 10B, 10C, 10D, and 10E illustrate cross-sectional side views of device structures as process operations are performed to fabricate the microelectronic device of FIG. 10A;

FIG. 11A illustrates a cross-sectional side view of a microelectronic device including an enhanced thermal hybrid bonding layer;

FIGS. 11B, 11C, and 11D illustrate cross-sectional side views of device structures as process operations are performed to fabricate the microelectronic device of FIG. 11A;

FIG. 12 illustrates an example microelectronic device assembly including a heat removal enhancement;

FIG. 13 illustrates exemplary systems employing an IC assembly including a heat removal enhancement; and

FIG. 14 is a functional block diagram of an electronic computing device, all in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the term predominantly indicates the predominant constituent (i.e., greater than 50% is the constituent of greatest proportion in the layer or material). The term substantially pure indicates the constituent is not less than 99% of the material. The term pure indicates the constituent is not less than 99.5% of the material and the term completely pure indicates the constituent is not less than 99.9% of the material. As used herein, the terms “monolithic”, “monolithically integrated”, and similar terms indicate the components of the monolithic overall structure form an indivisible whole not reasonably capable of being separated.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. Additional terms are defined herein below.

As discussed, thermal management of multichip composite devices is a problem that, if not addressed, can cause damage to a device or undesirable device throttling. In some embodiments, a microelectronic device includes a multichip composite device. As used herein, the term microelectronic device indicates a device including one or more integrated circuits to provide one or more functions. The microelectronic device may be at any level such as a packaged device, an assembly, a motherboard, or a consumer product. The term multichip composite device indicates a device having a number of chips or dies that are integrated and formed into a quasi-monolithic structure. Notably, the term composite indicates the structure has multiple components such as active dies, and dielectric material on and between the active dies. Furthermore, a handle die or handle layer may be attached to the multichip composite device, and the handle die or handle layer may be part of the quasi-monolithic structure. As used herein the terms base die and chiplets indicate dies or chips having active circuitry (i.e., circuitry that is to provide electronic or device functionality when in operation). For example, the base die and chiplets may include processor circuitry, memory circuitry, control circuitry, signal and power routing circuitry, and so on. The terms handle die, handle layer, structural member, or structural element indicates a structure that does not have such active circuitry. Instead, a handle die, handle layer, structural member, or structural element is to provide mechanical support and other functionality for the quasi-monolithic structure or microelectronic device.

In some embodiments, the multichip composite device includes one or more chiplets bonded to a surface (i.e., a top surface) of a base die. For example, the one or more chiplets may be bonded to the surface of the base die using hybrid bonding. Hybrid bonding indicates bonding between surfaces that each include metallization (e.g., metal pads) interspersed with dielectric material. Bonds are formed between corresponding metallization and between corresponding dielectric material to form a wafer to wafer bond, die to wafer bond, or die to die bond. Such hybrid bonds may be performed using any techniques known in the art. Furthermore, the multichip composite device includes inorganic dielectric material laterally adjacent to the one or more chiplets and over and/or on the base die. For example, the inorganic dielectric material may be formed over the hybrid bonded chiplets and base die to embed the chiplets in the inorganic dielectric material. As used herein, the term inorganic dielectric material indicates materials not having carbon to hydrogen bonds and being characterized as an electrical insulator. For example, an inorganic dielectric material may have a resistivity comparable to that of silicon dioxide. Although carbon may not be a foundational component of the inorganic dielectric material, the inorganic dielectric material may include carbon as, for example, a dopant.

The multichip composite device may be attached to a handle die or handle layer. As discussed, the handle die or handle layer offers mechanical stability and other functionality. Notably, prior use of organic mold compounds in 3D die stacks allowed for thicker chiplets as the organic mold compound can be easily formed at thicker dimensions. This allowed for chiplets having thicknesses of about 300 microns mounted on base dies of about 100 microns. However, the transition to inorganic dielectric materials, which offers a variety of advantages, necessitates the use of much thinner chiplets, such as those of about 20 microns. Such base die and chiplet/inorganic dielectric stacks do not have the mechanical stability to withstand subsequent processing. The multichip composite device, as discussed, is then attached to a handle die or handle layer to offer mechanical stability.

The techniques and structure discussed herein offer a variety of thermally enhanced handle dies, handle layers, and/or bonding layers to more efficiently remove heat from the multichip composite device. The multichip composite device may also be characterized as a 3D stack, 3D composite device, 3D quasi-monolithic structure, or the like. Typically, such enhancement is over the typical use of a crystalline silicon handle die and a bonding layer of silicon dioxide. Use of a passive silicon die as the handle die and a silicon dioxide layer disadvantageously does not provide adequate heat spreading from the chiplets. The techniques and structures discussed herein may include any combination of a thermally enhanced passive handle die or handle layer containing one or more materials with high thermal conductivity, a handle die with integrated fluidic cooling, and a thermally enhanced bonding layer that deploys a high thermal conductivity material. Such techniques and structures improve heat transfer, resulting in lower temperatures in the chiplets and/or base die, thereby allowing higher power capability and performance.

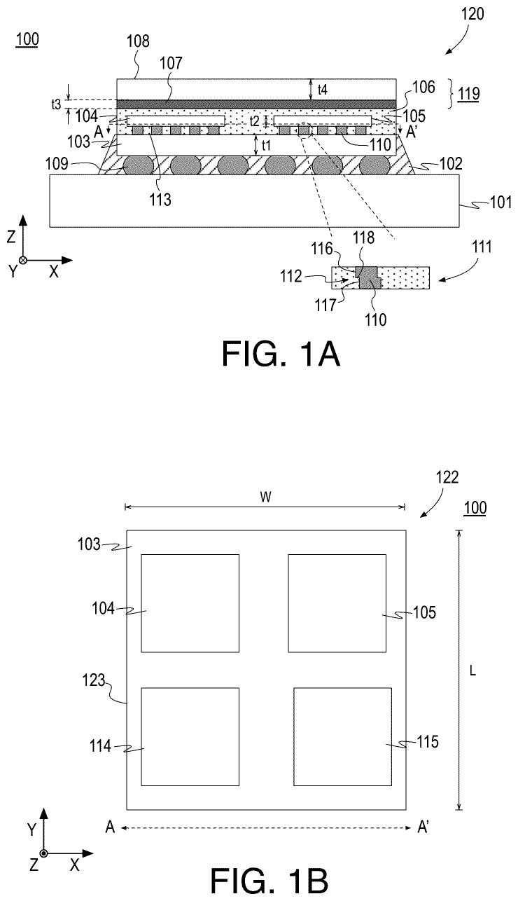

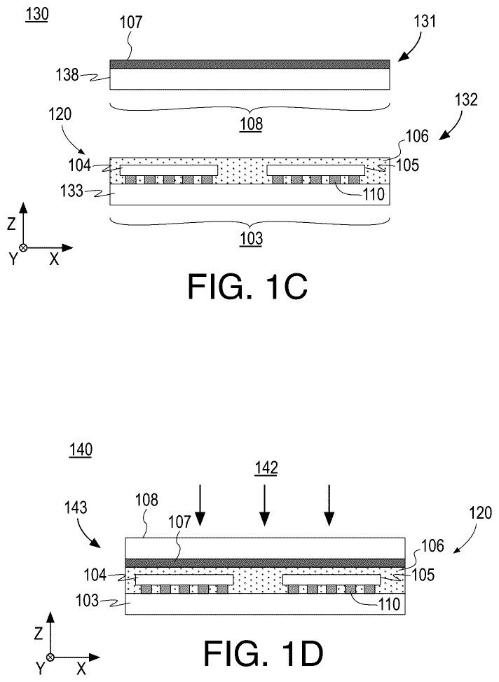

FIG. 1A illustrates a cross-sectional side view of a microelectronic device 100 including a handle die side heat removal layer 107, arranged in accordance with some embodiments. FIG. 1B illustrates a cross-sectional plan view taken at plane A-A′ in FIG. 1A. As shown in FIG. 1A, microelectronic device 100 includes any number of chiplets 104, 105 bonded to a surface 113 of a base die 103. As discussed, the term chiplet indicates an active circuitry device (i.e., circuitry that is to provide functionality when in operation). For example, a chiplet may contain circuitry to perform a defined subset of functionality. The term base die also indicates an active circuitry device.

Chiplets 104, 105 may be bonded to surface 113 of base die 103 using any suitable technique or techniques such as hybrid bonding to form die level interconnects 110. For example, surfaces including metallization interspersed among dielectric material may be formed on each of chiplets 104, 105 and surface 113 of base die 103. In some embodiments, the patterning of the surfaces matches metal to metal and dielectric to dielectric for hybrid bonding between chiplets 104, 105 and base die 103. Such surfaces are then brought together optionally under pressure and/or heat to meld the metal to form die level interconnects 110 and, optionally, to meld the dielectric material to form the hybrid bond. As shown with respect to enlarged view 111, in some embodiments, die level interconnects 110 may include a misalignment 112 indicative of the hybrid bond. Misalignment 112 may include, for example, a first sidewall 116 misaligned with a second sidewall 117 such that a lateral offset 118 (i.e., measured in the x-dimension) is therebetween. In some embodiments, lateral offset 118 is in the range of 10 to 500 nm. For example, lateral offset 118 may be not less than 10 nm, not less than 25 nm, or not less than 50 nm. Although any thicknesses may be used, in some embodiments, base die 103 may have a thickness t1 between 75 and 150 microns. In some embodiments, base die 103 has a thickness t1 between 50 and 80 microns. In some embodiments, base die 103 has a thickness t1 of about 100 microns. In some embodiments, chiplets 104, 105 have thicknesses t2 between 20 and 50 microns. In some embodiments, chiplets 104, 105 have thicknesses t2 of not more than 50 microns, with thicknesses t2 in the range of 20 to 30 microns being advantageous.

As shown in FIG. 1A, an inorganic dielectric material 106 is filled in between chiplets 104, 105, on exposed portions of base die 103 and, optionally, over chiplets 104, 105. In the illustrated example, inorganic dielectric material 106 is formed over chiplets 104, 105. In other examples, inorganic dielectric material 106 is partially removed (i.e., polished back) to expose top surfaces of chiplets 104, 105. In such examples, another inorganic dielectric material may be formed over the exposed top surfaces to provide a bonding layer. The bonding layer may be the same material as inorganic dielectric material 106 or they may be different. As discussed further herein below, in some embodiments, the bonding layer includes a material having a higher thermal conductivity than inorganic dielectric material 106. Inorganic dielectric material 106 may be any suitable inorganic dielectric material such as silicon dioxide. Notably, the thin chiplets 104, 105 at least partially enable the use of such advantageous inorganic dielectric materials. Multichip composite device 120 includes one or more of chiplets 104, 105 connected to surface 113 of base die 103, and inorganic dielectric material 106 laterally adjacent one or more of chiplets 104, 105 and over at least a portion of base die 103.

A handle structure 119 is bonded to the top of multichip composite device 120 using inorganic dielectric material 106 or the discussed bonding layer. Handle structure 119 provides mechanical robustness during processing, packaging, and so on, and handle structure 119 aids in heat spreading and heat removal from chiplets 104, 105 and base die 103 to a thermal solution, which is illustrated herein below. Handle structure 119 may be characterized as a handle die, a handle layer, a multilayer handle stack, a structural member, a structural element, or the like. In some embodiments, handle structure 119 includes a handle die 108 and heat removal layer 107. Herein, various components (such as handle die 108) are labeled as a handle die for the sake of clarity; however, such components may also be characterized as a structural member or a structural element.

As shown in FIG. 1B, where inorganic dielectric material 106 is not shown for the sake of clarity of presentation, chiplets 104, 105, any number of additional chiplets 114, 115, having the same or similar characteristics with respect to chiplets 104, 105, may be arrayed over base die 103. Base die 103 has an area 122, defined by edges 123 thereof, having a width W and a length L. In some embodiments, chiplets 104, 105, 114, 115 are arranged entirely within area 122 such that no edge of chiplets 104, 105, 114, 115 extends beyond edges 123. In some embodiments, handle structure 119 substantially shares area 122 with base die 103 and edges of handle structure 119 are substantially vertically aligned. For example, as discussed further herein below, fabrication of base die 103 and handle structure 119 may be performed at the wafer level (with chiplets 104, 105, 114, 115 attached to the base die wafer using die to wafer attachment), and the overall structure may be diced such that shared edges between base die 103 and handle structure 119 are formed (i.e., such that their outer edges are vertically aligned).

Returning to FIG. 1A, heat removal layer 107 is on handle die 108 (or a structural member or element), which is over multichip composite device 120. Notably, heat removal layer 107 is made of a material or materials having a greater thermal conductivity than handle die 108 and having a thickness t3 less than a thickness t4 of handle die 108. In some embodiments, handle die 108 has a thickness t4 in the range of 60 to 120 microns, bringing an overall thickness (from the bottom of base die 103 to the top of handle die 108) into the range of about 150 to 200 microns. Other handle die thicknesses may be used, such as thicknesses t4 in the range of 80 to 100 microns, or a thickness t4 of not less than 50 microns. Notably, depending on the mechanical properties required, handle die 108 thickness t4, the modulus of handle die 108, and other properties may be adjusted to meet the needs of the application of microelectronic device 100. Such needs differ depending on the sizes of the dies or the package, and other characteristics of the application. In some embodiments, handle die 108 is a crystalline silicon material. For example, handle die 108 may be silicon diced from a silicon wafer.

A relatively thin heat removal layer 107 is formed on handle die 108. Due to the high thermal conductivity of heat removal layer 107, a relatively thin layer may be deployed. In some embodiments, heat removal layer 107 has a thickness t3 in the range of 0.5 to 20 microns. In some embodiments, heat removal layer 107 has a thickness t3 of not more than 20 microns, not more than 10 microns, or not more than 5 microns. Heat removal layer 107 may include any material or materials having a greater thermal conductivity than that of handle die 108. In some embodiments, the material or composite of materials of heat removal layer 107 has a thermal conductivity of not less than twice the thermal conductivity of handle die 108. In some embodiments, the material or composite of materials of heat removal layer 107 has a thermal conductivity of not less than five times the thermal conductivity of handle die 108. In some embodiments, the material or composite of materials of heat removal layer 107 has a thermal conductivity of not less than seven times the thermal conductivity of handle die 108.

As discussed, in some embodiments, handle die 108 is crystalline silicon, having a thermal conductivity of about 140 W/m-K. In some embodiments, heat removal layer 107 is or includes crystalline or polycrystalline diamond. In some embodiments, heat removal layer 107 is or includes crystalline or polycrystalline diamond having a thermal conductivity of not less than 400 W/m-K. In some embodiments, heat removal layer 107 is or includes crystalline or polycrystalline diamond having a thermal conductivity of not less than 1,000 W/m-K. In some embodiments, heat removal layer 107 is or includes copper. In some embodiments, heat removal layer 107 is or includes copper having a thermal conductivity of not less than 300 W/m-K. In some embodiments, heat removal layer 107 is or includes boron and nitrogen (i.e., a compound including boron and nitrogen, boron nitride). In some embodiments, heat removal layer 107 is or includes boron and nitrogen having a thermal conductivity of not less than 250 W/m-K. In some embodiments, heat removal layer 107 is or includes boron and arsenic (i.e., a compound including boron and arsenic, boron arsenide). In some embodiments, heat removal layer 107 is or includes boron and arsenic having a thermal conductivity of not less than 300 W/m-K. In some embodiments, heat removal layer 107 is or includes silicon and carbon (i.e., a compound including silicon and carbon, silicon carbide). In some embodiments, heat removal layer 107 is or includes silicon and carbon having a thermal conductivity of not less than 300 W/m-K. In some embodiments, heat removal layer 107 is or includes aluminum and nitrogen (i.e., a compound including aluminum and nitrogen, aluminum nitride). In some embodiments, heat removal layer 107 is or includes aluminum and nitrogen having a thermal conductivity of not less than 250 W/m-K. In some embodiments, heat removal layer 107 includes a combination of two or more of such materials. Other high thermal conductivity material layers may be used.

Heat removal layer 107, due to its high thermal conductivity, spreads heat from chiplets 104, 105 and base die 103 more effectively than, for example, a silicon die. As shown in FIG. 1A, microelectronic device 100 further includes a package substrate 101 coupled to base die 103 by package level interconnects 109, which may be any suitable interconnects such as solder balls or the like. Furthermore, an optional underfill 102 may be provided.

FIGS. 1C and 1D illustrate cross-sectional side views of device structures as process operations are performed to fabricate microelectronic device 100, arranged in accordance with some embodiments. FIG. 1C illustrates the formation of device structures 130, as follows. As shown, a handle wafer 138 is received for processing and heat removal layer 107 is formed thereon at a deposition operation 131. Handle wafer 138 may include any material discussed with respect to handle die 108. Heat removal layer 107 may be formed using any suitable technique or techniques such as chemical vapor deposition (CVD), plasma enhanced or assisted CVD (PECVD), atomic layer deposition (ALD), electroplating, additive manufacturing, e.g., cold spray, or the like. Notably, by forming heat removal layer 107 on handle wafer 138, prior to bonding to a composite wafer, high thermal conductivity materials can be advantageously grown at high temperatures, which would not be possible in the presence of other components of microelectronic device 100.

Furthermore, FIG. 1C illustrates the formation of multichip composite device 120 on wafer 133 at multichip composite device operations 132. Multichip composite device 120 may be formed using any suitable technique or techniques. In some embodiments, devices and metallization layers of many base dies 103 are formed on and over substrate wafer 133. Subsequently, instances of chiplets 104, 105 are attached to each base die 103 using hybrid bonding as discussed herein. For example, chiplets 104, 105 may be bonded in a die (or chiplet) to wafer manner Inorganic dielectric material 106 is then formed using any suitable technique or techniques such as CVD, PECVD, or the like. Inorganic dielectric material 106 may be planarized and, in some embodiments, a bonding layer (often of the same material as inorganic dielectric material 106).

FIG. 1D illustrates a device structure 140 similar to device structures 130 after a bonding operation 142 and dicing operation 143. As shown, handle wafer 138, including heat removal layer 107, and substrate wafer 133, including multichip composite device 120, are then bonded. In some embodiments, a thin bonding layer (not shown) is grown on heat removal layer 107 prior to bonding. Bonding operation 142 may be performed using any suitable technique or techniques. In some embodiments, bonding operation 142 is performed at the wafer level and subsequent dicing operation 143 is performed. Alternatively, in some embodiments, one or both of handle wafer 138 and substrate wafer 133 are diced prior to bonding. For example, handle dies 108 may be diced from handle wafer 138 and bonded to substrate wafer 133 (i.e., in a die to wafer manner). In embodiments where handle wafer 138 and substrate wafer 133 are diced together, they share an area and vertically aligned edges as discussed with respect to FIG. 1B.

With reference to FIG. 1A, subsequently, device structure 140 may be packaged as known in the art to form microelectronic device 100. For example, device structure 140 may be bump attached to package substrate 101 and underfill 102 may be provided. Microelectronic device 100 may then be incorporated in any suitable form factor device.

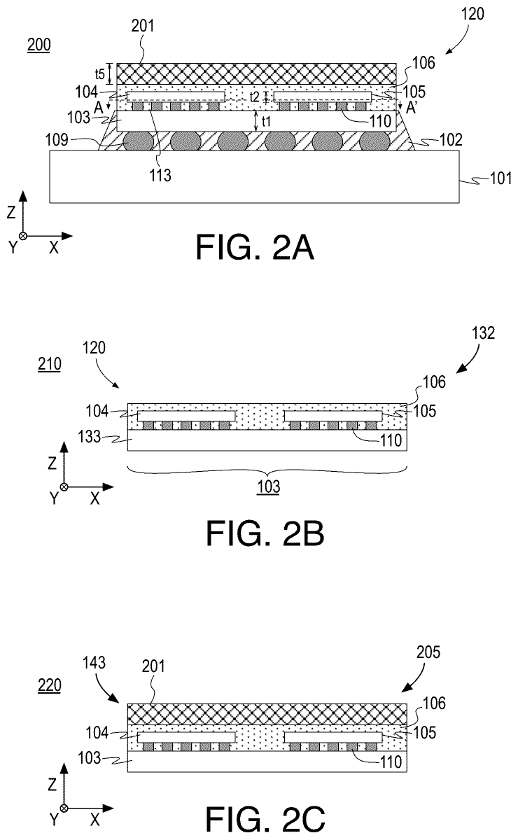

FIG. 2A illustrates a cross-sectional side view of a microelectronic device 200 including a high thermal conductivity handle layer or die 201, arranged in accordance with some embodiments. Notably, FIG. 1B also illustrates cross-sectional plan view taken at plane A-A′ in FIG. 2A. Furthermore, in FIG. 2A and elsewhere herein, like numerals indicate like components that may have any characteristics discussed elsewhere herein. Such details, materials, dimensions, and the like are not repeated for the sake of brevity. As shown in FIG. 2A, microelectronic device 200 includes chiplets 104, 105 bonded to surface 113 of base die 103. Inorganic dielectric material 106 is filled in between chiplets 104, 105, on exposed portions of base die 103 and, optionally, over chiplets 104, 105. Inorganic dielectric material 106 may be over chiplets 104, 105 or a bonding layer may be provided as discussed above.

Handle layer or die 201 (or a structural member or element) is on the top of multichip composite device 120, either on inorganic dielectric material 106 or the bonding layer. Handle die 201 may be characterized as a handle layer or handle die. For example, a handle layer may be attached to, formed directly on, or deposited directly on multichip composite device 120, and subsequently diced to a shape of a die. Alternatively, handle die 201 may be diced and then attached to multichip composite device 120. In either case, handle die 201 does not include active circuitry (i.e., circuitry that is to provide electronic or device functionality when in operation). Handle die 201 provides mechanical robustness during processing, packaging, etc., and aids in heat spreading and removal from chiplets 104, 105 and base die 103.

In the example of FIG. 2A, handle die 201 is or includes at least one material that is more thermally conductive than crystalline silicon (i.e., about 140 W/m-K). In some embodiments, handle die 201 is or includes at least one material that has a thermally conductivity of not less than 200 W/m-K. In some embodiments, handle die 201 is or includes at least one material that has a thermally conductivity of not less than 250 W/m-K. In some embodiments, handle die 201 is or includes at least one material that has a thermally conductivity of not less than 400 W/m-K.

In some embodiments, handle die 201 has a thermally conductivity of not less than 200 W/m-K, not less than 250 W/m-K, or not less than 400 W/m-K. For example, as a composite structure, handle die 201 may have an average thermal conductivity of not less than 200 W/m-K, 250 W/m-K, or 400 W/m-K.

Handle die 201 is on multichip composite device 120. Notably, handle die 201 is made of a material or materials having a high thermal conductivity, and handle die 201 has a thickness that provides mechanical stability during processing. In some embodiments, handle die 201 has a thickness t5 in the range of 25 to 120 microns, bringing an overall thickness (from the bottom of base die 103 to the top of handle die 201) into the range of about 100 to 200 microns. In some embodiments, handle die 201 has a thickness t5 of not less than 25 microns. In some embodiments, handle die 201 has a thickness t5 of not less than 50 microns. In some embodiments, handle die 201 has a thickness t5 in the range of 50 to 400 microns. For example, thickness t5 of handle die 201 may be adjusted to meet thermomechanical reliability and warpage control requirements.

Handle die 201 may include any material or materials having a high thermal conductivity, as discussed above. In some embodiments, the material or composite of materials of handle die 201 has a thermal conductivity of not less than twice that of crystalline silicon. In some embodiments, the material or composite of materials of handle die 201 has a thermal conductivity of not less than five times that of crystalline silicon. In some embodiments, the material or composite of materials of handle die 201 has a thermal conductivity of not less than seven that of crystalline silicon.

In some embodiments, handle die 201 is or includes crystalline or polycrystalline diamond. In some embodiments, handle die 201 is or includes crystalline or polycrystalline diamond. In some embodiments, handle die 201 is or includes crystalline or polycrystalline diamond having a thermal conductivity of not less than 400 W/m-K. For example, when formed on multichip composite device 120, higher thermal conductivities may not be attainable. In some embodiments, handle die 201 is or includes crystalline or polycrystalline diamond having a thermal conductivity of not less than 1,000 W/m-K. In some embodiments, handle die 201 is or includes crystalline or polycrystalline diamond having a thermal conductivity of not less than 2,000 W/m-K. In some embodiments, handle die 201 is or includes copper. In some embodiments, handle die 201 is or includes copper having a thermal conductivity of not less than 300 W/m-K. In some embodiments, handle die 201 is or includes boron and nitrogen (i.e., a compound including boron and nitrogen, boron nitride). In some embodiments, handle die 201 is or includes boron and nitrogen having a thermal conductivity of not less than 250 W/m-K. In some embodiments, handle die 201 is or includes boron and arsenic (i.e., a compound including boron and arsenic, boron arsenide). In some embodiments, handle die 201 is or includes boron and arsenic having a thermal conductivity of not less than 300 W/m-K. In some embodiments, handle die 201 is or includes silicon and carbon (i.e., a compound including silicon and carbon, silicon carbide). In some embodiments, handle die 201 is or includes silicon and carbon having a thermal conductivity of not less than 300 W/m-K. In some embodiments, handle die 201 is or includes aluminum and nitrogen (i.e., a compound including aluminum and nitrogen, aluminum nitride). In some embodiments, handle die 201 is or includes aluminum and nitrogen having a thermal conductivity of not less than 250 W/m-K. In some embodiments, handle die 201 includes a combination of two or more of such materials. For example, handle die 201 may be a composite of copper and diamond or a composite of silicon and diamond. Other high thermal conductivity material layers may be used.

Handle die 201, due to its high thermal conductivity, spreads heat from chiplets 104, 105 and base die 103 more effectively than, for example, a silicon die. Microelectronic device 200 further includes package substrate 101 coupled to base die 103 by package level interconnects 109, and optional underfill 102.

FIGS. 2B and 2C illustrate cross-sectional side views of device structures as process operations are performed to fabricate microelectronic device 200, arranged in accordance with some embodiments. FIG. 2B illustrates the formation of device structures 210, as discussed above with respect to FIG. 1C. For example, multichip composite device 120 may be formed on and over wafer 133 at multichip composite device operations 132. Such operations may be performed using any suitable technique or techniques such that devices and metallization layers of many base dies 103 are formed on and over substrate wafer 133, chiplets 104, 105 are attached to each base die 103 using hybrid bonding or the like, and inorganic dielectric material 106 is then formed. Inorganic dielectric material 106 may be planarized and, in some embodiments, a bonding layer (e.g., the same material as inorganic dielectric material 106) is formed.

FIG. 2C illustrates a device structure 220 similar to device structure 210 after a deposition operation 205 and dicing operation 143. As shown, a handle layer may be formed directly on or over multichip composite device 120. The handle layer may then be diced along with substrate wafer 133 to form handle die 201 and base die 103. The handle layer may be formed using any suitable (e.g., low temperature) deposition techniques. Alternatively, the handle layer may be deposited on a handle wafer, which is bonded to substrate wafer 133, and the handle wafer is subsequently removed. For example, bonding operation 142 as discussed with respect to FIG. 1D may be deployed with handle wafer 138 being removed using back side grind, etch, delamination, or other techniques. With reference to FIG. 2A, subsequently, device structure 220 may be packaged to form microelectronic device 200 by, for example, bump attached to package substrate 101 and a subsequent underfill operation to form underfill 102. Microelectronic device 200 may then be incorporated in any suitable form factor device.

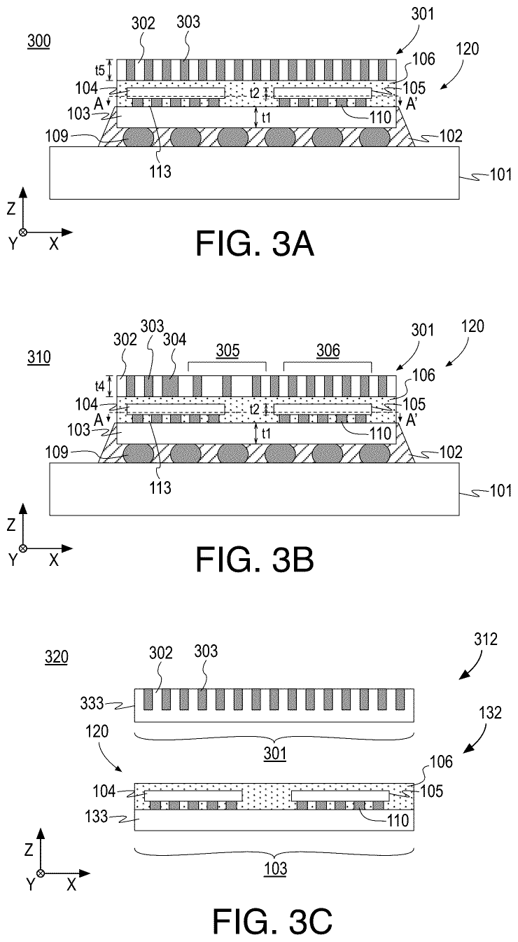

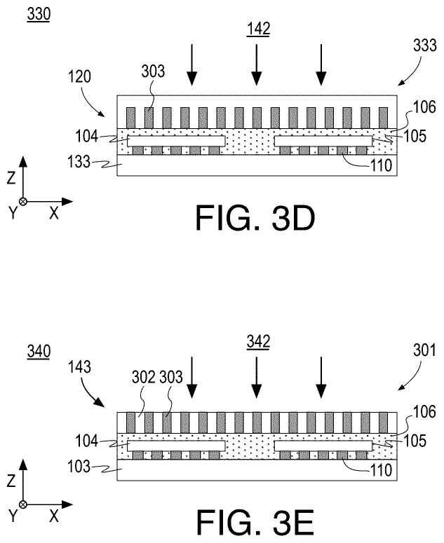

FIG. 3A illustrates a cross-sectional side view of a microelectronic device 300 including a high thermal conductivity handle die 301 including through vias 303, arranged in accordance with some embodiments. FIG. 1B also illustrates cross-sectional plan view taken at plane A-A′ in FIG. 3A. As shown, microelectronic device 300 includes chiplets 104, 105 bonded to surface 113 of base die 103, inorganic dielectric material 106 between chiplets 104, 105, on exposed portions of base die 103 and, optionally, over chiplets 104, 105.

Handle die 301 (or a structural member or element) is on the top of multichip composite device 120. For example, handle die 301 may be on inorganic dielectric material 106 or a bonding layer. In the example of FIG. 3A, handle die 301 includes through vias 303 extending vertically through a substrate layer 302. In some embodiments, substrate layer 302 is crystalline silicon and through vias 303 may be characterized as through silicon vias (TSVs). Through vias 303 may be any material having a thermal conductivity greater than that of substrate layer 302. For example, through vias 303 may include any material or materials discussed with respect to heat removal layer 107, such as diamond, copper, boron nitride, boron arsenide, silicon carbide, or aluminum nitride, or a compound, composite, or a hybrid with the aforementioned materials, with copper being particularly advantageous. In some embodiments, through vias 303 include a metal such as copper (as discussed), aluminum, gold, platinum, palladium, or others.

Handle die 301, due to through vias, spreads heat from chiplets 104, 105 and base die 103 more effectively than, for example, a silicon die. Microelectronic device 200 further includes package substrate 101 coupled to base die 103 by package level interconnects 109, and optional underfill 102.

FIG. 3B illustrates a cross-sectional side view of a microelectronic device 310 including a high thermal conductivity handle die 301 including through vias of differing sizes and densities, arranged in accordance with some embodiments. For example, by controlling the size, placement, and/or density of through vias 303, 304, and so on, the effective thermal conductivity of handle die 301 can be controlled and/or further raised to minimize thermal resistance. For example, larger diameter vias 304 (i.e., having a diameter of not less than 1.5 times, twice, or 3 times that of vias 303) may be located over hot spots. Similarly, vias having a greater density 306 may be placed over chiplets having hot spots or those known to run hotter. For example, density 306 may be 1.5 times, twice, or 3 times that of a lower density 305 region. Greater density 306 regions may offer the advantages of greater heat removal while lower density 305 regions may offer the advantages of lower cost. In some embodiments, a number of first through vias in a greater density 306 region of handle die 301 has a first density and a number of second through vias in lower density 305 region of handle 301 die has a second density less than the first density. In some embodiments, the second density is less than two-thirds, less than half, or less than one-third that of the first density. The density may be measured in area (in the x-y plane) of through vias over the area of substrate in particular sample regions at a particular height in the z-dimension.

FIGS. 3C, 3D, and 3E illustrate cross-sectional side views of device structures as process operations are performed to fabricate microelectronic devices 300, 310, arranged in accordance with some embodiments. FIG. 3C illustrates the formation of device structures 320, as follows. As shown, a wafer 333, such as silicon wafer is received for processing and through vias 303 are formed therein at a through via formation operation 312. In some embodiments, through vias 303 are formed as partial through vias, as shown. In some embodiments, through vias extend through wafer 333. Through vias 303 may be formed using any suitable technique or techniques such as lithography and etch techniques to form open vias and metal fill techniques such as deposition techniques (as discussed with respect to heat removal layer 107) to form through vias 303 in the open vias. Optional planarization techniques may then be performed to provide a planar top surface. Also as shown in FIG. 3C, multichip composite device 120 is formed on wafer 133 at multichip composite device operations 132. Multichip composite device 120 may be formed using any suitable technique or techniques as discussed with respect to FIG. 1C.

FIG. 3D illustrates a device structure 330 similar to device structures 320 after bonding operation 142. As shown, wafer 333, including through vias 303, and substrate wafer 133, including multichip composite device 120, are then bonded. In some embodiments, a thin bonding layer (not shown) is grown on wafer 333 prior to bonding. Bonding operation 142 may be performed using any suitable technique or techniques. In some embodiments, bonding operation 142 is performed at the wafer level.

FIG. 3E illustrates a device structure 340 similar to device structures 330 after a back side removal operation 342 and dicing operation 143. Back side removal operation 342 may be performed using any suitable technique or techniques such as back side grind, etch, or the like. As shown, back side removal operation 342 exposes through vias 303 (i e, making through vias 303 from partial through vias). A subsequent dicing operation 143 may then be performed. Alternatively, dicing may be performed prior to attach.

With reference to FIG. 3A, subsequently, device structure 340 may be packaged to form microelectronic device 300. For example, device structure 340 may be bump attached to package substrate 101 and underfill 102 may be formed. Microelectronic device 300 may then be incorporated in any suitable form factor device.

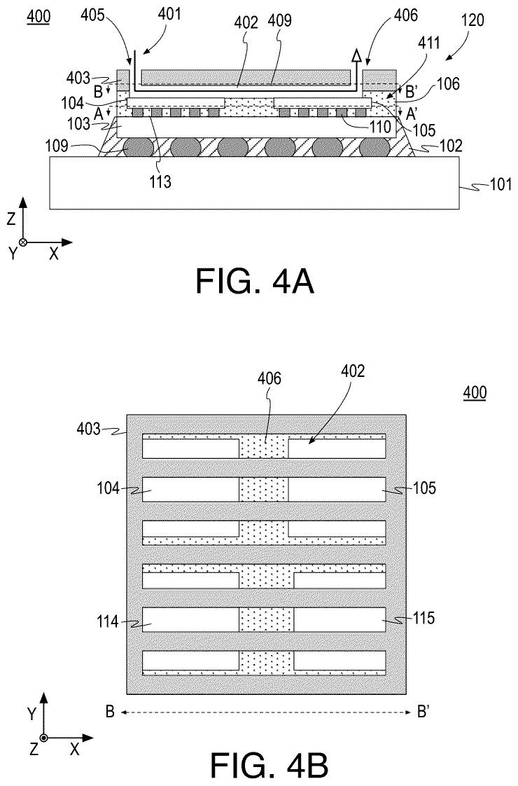

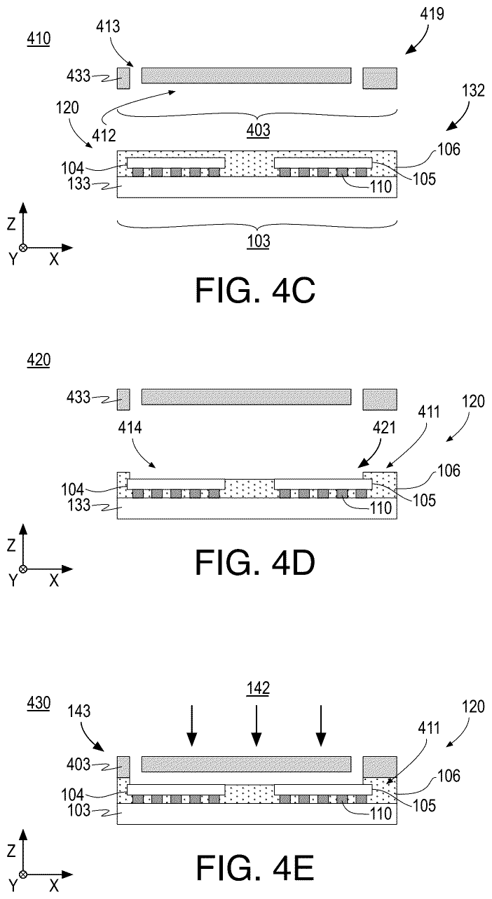

FIG. 4A illustrates a cross-sectional side view of a microelectronic device 400 incorporating integrated lateral fluidic cooling, arranged in accordance with some embodiments. FIG. 1B also illustrates cross-sectional plan view taken at plane A-A′ in FIG. 4A. FIG. 4B illustrates a cross-sectional plan view taken at plane B-B′ in FIG. 4A. As shown, microelectronic device 400 includes chiplets 104, 105 bonded to surface 113 of base die 103, inorganic dielectric material 106 between chiplets 104, 105, on exposed portions of base die 103 and, optionally, over chiplets 104, 105.

Handle die 403 (or a structural member or element) is on the top of multichip composite device 120. For example, handle die 403 may be on inorganic dielectric material 106 or a bonding layer. In the example of FIG. 4A, handle die 403 includes any number of microchannels 402 for flow 401 of a cooling fluid (not shown) therein. With reference to FIG. 4B, one or more of microchannels 402 extend (vertically) between surfaces of chiplets 104, 105, 114, 115 and a pertinent portion 409 of handle die 403. That is, each of microchannels 402 provides an opening such that the opening is at least partially enclosed by a top surface of one or more of chiplets 104, 105, 114, 115 and an opposing surface of handle die 403. Handle die 403 may be any material discussed with respect to handle dies 108 and 201. In some embodiments, handle die 403 is at least partially formed of crystalline silicon.

In the example of microelectronic device 400, active fluidic cooling is integrated into handle die 403 (which may also be characterized as a handle layer). Microchannels 402 extend laterally across top surfaces of chiplets 104, 105 to provide a substantially lateral flow of the cooling fluid across the top surfaces. As shown, microchannels 402 are formed by openings in handle die 403 and, optionally, in openings of inorganic dielectric material 106 such that the openings are aligned. The term microchannels indicates a channel to convey a heat transfer fluid with the multiple microchannels providing discrete separate channels or a network of channels. Notably, the plural microchannels does not indicate separate discrete channels are deployed. Such microchannels 402 may be provided in any pattern in the x-y plane such as patterns of multiple parallel microchannels (as shown), serpentine patterns, networks of branching microchannels, or the like. Microchannels 402 couple to a heat exchanger (not shown) that removes heat from and cools the heat transfer fluid before re-introduction to microchannels 402. The flow of fluid within microchannels 402 may be provided by a pump or other fluid flow device. The operation of the heat exchanger, pump, etc. may be controlled by a controller.

In some embodiments, one or more of microchannels 402 are in fluid communication with one or more inlets 405 and one or more outlets 406. Inlet 405 and outlet 406 may be coupled to inlet and outlet tubing, respectively. Microchannels 402 may have any suitable dimensions. In some embodiments, microchannels 402 have a width (in the y-dimension) of not less than 2 microns, not less than 5 microns, or not less than 10 microns. In some embodiments, microchannels 402 have a height (in the y-dimension) of not less than 2 microns, not less than 5 microns, or not less than 10 microns. The heat transfer fluid deployed in microchannels 402 may be single phase (liquid or gas) or multi-phase (liquid and gas), and may include any suitable material. In some embodiments, the heat transfer fluid is a water, dielectric refrigerant, or other coolant. In some embodiments, a bond layer portion 411 is used around the periphery of handle die 403 to create a seal to contain fluid flow.

FIGS. 4C, 4D, and 4E illustrate cross-sectional side views of device structures as process operations are performed to fabricate microelectronic device 400, arranged in accordance with some embodiments. It is noted that the operations of FIGS. 4C, 4D, and 4E may also be used to fabricate any other integrated fluidic cooling microelectronic devices discussed herein. FIG. 4C illustrates the formation of device structures 410, as follows. As shown, a wafer 433, such as silicon wafer is received for processing and openings 412, 413 are patterned into wafer 433 using any suitable technique or techniques such as lithography and etch techniques at patterning operation 419. Openings 412, 413 match the desired pattern for microchannels 402, inlet 405, and outlet 406 and may be formed at a wafer level for later dicing to the die level. In some embodiments, openings 412, 413 include trenches or trench openings 412 for microchannels 402 and through openings 413 for inlet 405 and outlet 406. Also as shown in FIG. 4C, multichip composite device 120 is formed on wafer 133 at multichip composite device operations 132. Multichip composite device 120 may be formed using any suitable technique or techniques as discussed with respect to FIG. 1C.

FIG. 4D illustrates device structures 420 similar to device structures 320 after patterning operation 421 to form openings 414. Patterning operation 421 may include any suitable technique or techniques such as lithography and etch operations. As shown, portions of inorganic dielectric material 106 (or a bonding layer on inorganic dielectric material 106) are removed to form openings 414 while leaving bond layer portion 411 (or a portion of inorganic dielectric material 106) to provide a peripheral seal. In some embodiments, openings 414 match the pattern of openings 412. However, differing patterns may be used.

FIG. 4E illustrates device structure 430 similar to device structures 420 after bonding operation 142 and dicing operation 143. As shown, wafer 433, including openings 412, 413, and substrate wafer 133, including multichip composite device 120, are then bonded. In some embodiments, a thin bonding layer (not shown) is grown on wafer 433 prior to bonding. Bonding operation 142 may be performed using any suitable technique or techniques. In some embodiments, bonding operation 142 is performed at the wafer level and subsequent dicing operation 143 is performed. Alternatively, in some embodiments, one or both of wafer 433 and wafer 133 are diced prior to bonding. For example, handle dies 403 may be diced from wafer 433 and bonded to substrate wafer 133 (i.e., in a die to wafer manner). In embodiments where wafer 433 and substrate wafer 133 are diced together, they share an area and vertically aligned edges as discussed with respect to FIG. 1B.

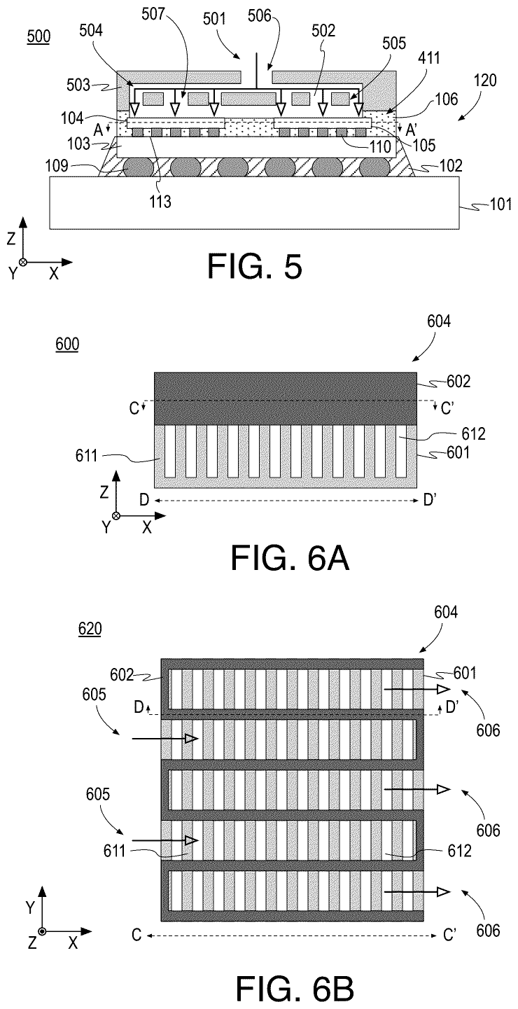

FIG. 5 illustrates a cross-sectional side view of a microelectronic device 500 incorporating integrated perpendicular fluidic cooling, arranged in accordance with some embodiments. FIG. 1B also illustrates cross-sectional plan view taken at plane A-A′ in FIG. 4A. Microelectronic device 500 includes chiplets 104, 105 bonded to surface 113 of base die 103, inorganic dielectric material 106 between chiplets 104, 105, on exposed portions of base die 103 and, optionally, over chiplets 104, 105.

Handle die 503 (or a structural member or element) is on the top of multichip composite device 120. For example, handle die 503 may be on inorganic dielectric material 106 or a bonding layer. In the example of FIG. 5, handle die 503 includes any number of microchannels 502 for flow 501 of a cooling fluid (not shown) therein. Microchannels 502 extend laterally and vertically in handle die 503 to direct flow 501 substantially perpendicular to top exposed surfaces of chiplets 104, 105. Microchannels 502 include openings at least partially enclosed by a top surface of one or more of chiplets 104, 105 and an opposing surface or surfaces of handle die 503. Handle die 503 may be any material discussed with respect to handle dies 108 and 201. In some embodiments, handle die 403 is at least partially formed of crystalline silicon.

In the example of microelectronic device 500, active fluidic cooling is integrated into handle die 503 (which may also be characterized as a handle layer). Microchannels 502 are formed by openings in handle die 403 and, optionally, in openings of inorganic dielectric material 106 such that the openings of microchannels provides fluid flow 501 that impinges on and is substantially perpendicular to a top surface of each of chiplets 104, 105. For example, an average flow vector of a portion of flow 501 may be substantially orthogonal to the top surface of one of chiplets 104, 105. Such microchannels 402 may be provided in any pattern in the x-y plane such as patterns of multiple parallel microchannels, serpentine patterns, networks of branching microchannels, or the like. In some embodiments, a top network 504 of microchannels 502 distributes the cooling fluid laterally (i.e., in the x-y plane) and a lower network 505 of microchannels 502 direct the cooling fluid downwardly to chiplets 104, 105 via ports 507. For example, port 507 of microchannels 502 is above a top surface of chiplet 104 to provide a substantially perpendicular flow of the cooling fluid onto the top surface of chiplet 104. The fluid may include any fluid discussed herein and may be controlled using an suitable fluid flow devices. In some embodiments, one or more of microchannels 502 are in fluid communication with one or more inlets 506 and one or more outlets (not shown in the plane of FIG. 5). Microchannels 502 may have any dimensions discussed with respect to microchannels 402. Handle die 503 may be fabricated as discussed with respect to FIGS. 4C, 4D, and 4E or a multilayer structure may be deployed.

FIG. 6A illustrates a cross-sectional side view of a handle die 600 having a multilayer structure for integration of perpendicular fluidic cooling, arranged in accordance with some embodiments. FIG. 6B illustrates a cross-sectional plan view taken at plane C-C′ in FIG. 6A. Also, as shown, FIG. 6A provides a cross-sectional side view taken at plane D-D′ in FIG. 6B. Although discussed with respect to providing a multilayer structure for integration of perpendicular fluidic cooling, handle die 600 may also be deployed in the context of the lateral cooling discussed with respect to FIG. 4A.

As shown, handle die 600 (or a structural member or element) includes a first structure 601 including a number of fins 611 having microchannels 612, and a second structure 602 having a serpentine pattern formed by patterned walls 604. For example, with reference to FIG. 6B, second structure 602 includes a manifold pattern defined by patterned walls 604 such that inlet flow 605 is directed laterally within second structure 602 (i.e., in the x-direction) and then downwardly (i.e., in the negative z-direction) by microchannels 612 of first structure 601. The fluid flow then flows laterally (i.e., in the y-direction) and then upwardly (i.e., in the positive z-direction) and exits as outlet flow 606. For example, microchannels 612 are within fins 611 (e.g., a number of silicon fin structures) and a manifold structure defined by second structure 602 is over the fin structures, such that the manifold structure to receive the cooling fluid and direct the cooling fluid into microchannels 612.

The design of handle die 600 enables direct substantially vertical impingement of the fluid flow onto chiplets 104, 105 as discussed above. In some embodiments, first structure 601 is silicon with fins 611 patterned therein by deep reactive-ion etch (DRIE) processing. In some embodiments, second structure 602 is deposited metal that is subsequently patterned. For example, the metal may be deposited using cold spray techniques, and patterned into the desired manifold shape by selective deposition, etching, or additive manufacturing. In some embodiments, second structure 602 is formed in silicon substrate, which is flipped and bonded to first structure 601. In such embodiments, the silicon substrate of the second structure 602 also forms a capping layer.

Discussion now continues with exemplary architectures to provide perpendicular fluidic cooling to surfaces of chiplets 104, 105. Such architectures may be deployed using handle dies fabricated in accordance with techniques discussed with respect to FIGS. 4C, 4D, and 4E or those discussed with respect to handle die 600.

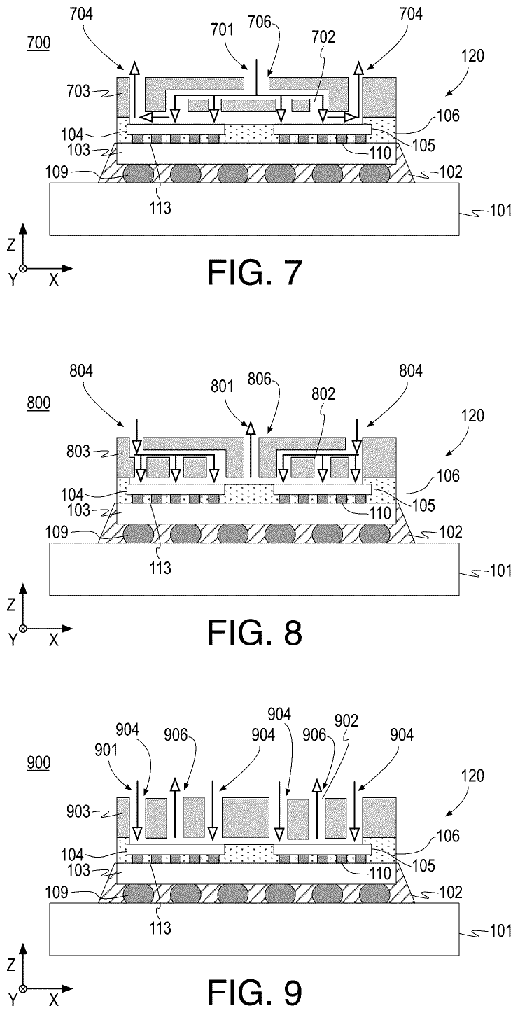

FIG. 7 illustrates a cross-sectional side view of a microelectronic device 700 incorporating integrated perpendicular fluidic cooling with a central fluid inlet port 706 and peripheral fluid outlet ports 704, arranged in accordance with some embodiments. Microelectronic device 700 includes chiplets 104, 105 bonded to surface 113 of base die 103, inorganic dielectric material 106 between chiplets 104, 105, on exposed portions of base die 103 and, optionally, over chiplets 104, 105.

Handle die 703 (or a structural member or element) is on the top of multichip composite device 120. For example, handle die 703 may be on inorganic dielectric material 106 or a bonding layer. In the example of FIG. 7, handle die 703 includes any number of microchannels 702 for flow 701 of a cooling fluid (not shown) therein. Microchannels 702 extend laterally and vertically in handle die 703 to direct flow 701 substantially perpendicular to top exposed surfaces of chiplets 104, 105. Furthermore, fluid inlet port 706 of handle die 703 extends into microchannels 702 at a center region of handle die 703, and fluid outlet ports 704 of handle die 703 extends out of microchannels 702 at a peripheral region of handle die 703. As used herein, the term central region indicates a region centered at the center of the handle die and including 25% of the area of the handle die. The term peripheral region indicates a region extending around the perimeter of the handle die and including 50% of the area of the handle die. As discussed herein, in microelectronic device 700, active fluidic cooling is integrated into handle die 703 via microchannels 702, which channel cooling fluid to chiplets 104, 105. For example, FIG. 7 illustrates an example manifold arrangement where all of the interior of the die complex is an inlet manifold with vertical downward inlet flow ports, and the fluid exits through outlet channels near the die edge complex.

FIG. 8 illustrates a cross-sectional side view of a microelectronic device 800 incorporating integrated perpendicular fluidic cooling with a central fluid outlet port 806 and peripheral fluid inlet ports 804, arranged in accordance with some embodiments. Microelectronic device 800 includes chiplets 104, 105 bonded to surface 113 of base die 103, inorganic dielectric material 106 between chiplets 104, 105, on exposed portions of base die 103 and, optionally, over chiplets 104, 105.

As shown, handle die 803 (or a structural member or element) is on multichip composite device 120 such as on inorganic dielectric material 106 or a bonding layer. In FIG. 8, handle die 803 includes any number of microchannels 802 for flow 801 of a cooling fluid (not shown) therein. Microchannels 802 extend laterally and vertically in handle die 803 to direct flow 801 including flow substantially perpendicular onto top exposed surfaces of chiplets 104, 105. Furthermore, fluid inlet ports 804 of handle die 803 extend out of microchannels 802 at a center region of handle die 803, and fluid outlet port 806 of handle die 803 extends out of microchannels 802 at a peripheral region of handle die 803. For example, FIG. 8 illustrates an example manifold arrangement where all of the interior of the die complex includes an outlet flow port and inlets manifold with vertical downward inlet flow ports near the die edge complex.

FIG. 9 illustrates a cross-sectional side view of a microelectronic device 900 incorporating integrated perpendicular fluidic cooling having an inlet port 904 and an outlet port 906 over chiplet 104, arranged in accordance with some embodiments. In the context of microelectronic device 900, a manifold for fluid flow 901 may be provided off die with inlet ports 904 and outlet ports 906 of coupled to the manifold using connections and/or tubing. As shown, microelectronic device 800 includes chiplets 104, 105 bonded to surface 113 of base die 103, inorganic dielectric material 106 between chiplets 104, 105, on exposed portions of base die 103 and, optionally, over chiplets 104, 105. Handle die 903 is on multichip composite device 120 such as on inorganic dielectric material 106 or a bonding layer.

In FIG. 9, handle die 903 (or a structural member or element) includes any number of microchannels 902 for fluid flow 901 of a cooling fluid (not shown) therein such that microchannels 902 extend vertically through handle die 903. As shown, inlet ports 904 are directly over chiplets 104, 105 to provide direct perpendicular flow impingement onto chiplets 104, 105. Also as shown, outlet ports 906 are optionally over chiplets 104, 105. In some embodiments, outlet ports 906 are outside of the area of chiplets 104, 105.

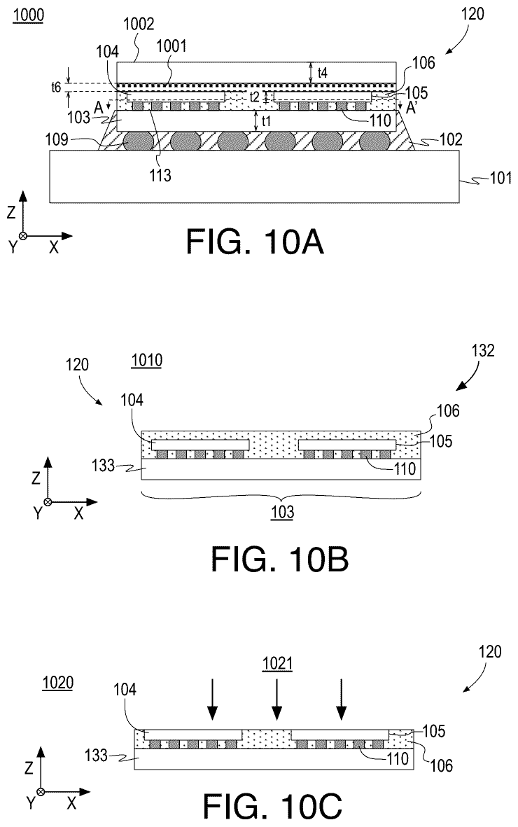

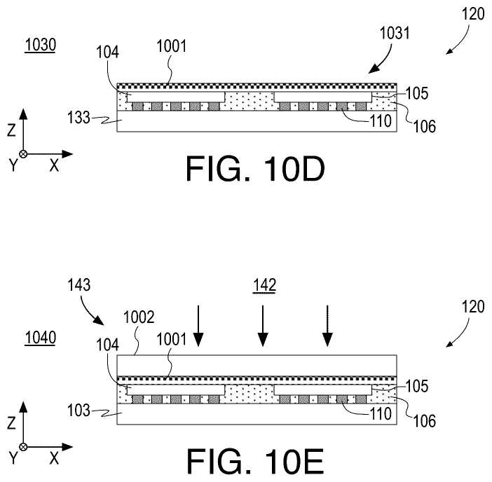

FIG. 10A illustrates a cross-sectional side view of a microelectronic device 1000 including an enhanced thermal bonding layer 1001, arranged in accordance with some embodiments. FIG. 1B illustrates a cross-sectional plan view taken at plane A-A′ in FIG. 10A. Microelectronic device 1000 includes any number of chiplets 104, 105 bonded to surface 113 of base die 103. Inorganic dielectric material 106 is filled in between chiplets 104, 105, on exposed portions of base die 103. In the example of FIG. 10A, inorganic dielectric material 106 is not over chiplets 104, 105.

Instead, enhanced thermal bonding layer 1001 is on top surfaces of chiplets 104 and on regions of inorganic dielectric material 106. Inorganic dielectric material 106 may be any inorganic dielectric such as silicon dioxide Enhanced thermal bonding layer 1001 may be any suitable material having a greater thermal conductivity than silicon dioxide (e.g., about 1 W/m-K). In some embodiments, enhanced thermal bonding layer 1001 includes one or a combination of dielectric materials having a greater thermal conductivity than silicon dioxide. In some embodiments, enhanced thermal bonding layer 1001 is or includes silicon and nitrogen (i.e., a compound including silicon and nitrogen, silicon nitride). In some embodiments, enhanced thermal bonding layer 1001 is or includes silicon and nitrogen having a thermal conductivity of not less than 20 W/m-K. In some embodiments, enhanced thermal bonding layer 1001 is or includes silicon and carbon (i.e., a compound including silicon and carbon, silicon carbide). In some embodiments, enhanced thermal bonding layer 1001 is or includes silicon and carbon having a thermal conductivity of not less than 490 W/m-K. Other high thermal conductivity dielectric materials may be used.

In some embodiments, enhanced thermal bonding layer 1001 includes one or a combination of metals having a greater thermal conductivity than silicon dioxide. In some embodiments, enhanced thermal bonding layer 1001 is or includes copper. In some embodiments enhanced thermal bonding layer 1001 is or includes copper having a thermal conductivity of not less than 300 W/m-K. Other metals such as titanium, gold, or others may be used.

Notably, the example of FIG. 10A enhances the bond layer to a material that is more thermally conductive than the dielectric used as gap fill between chiplets 104, 105, the enhanced bond layer may be silicon nitride, silicon carbide, other high thermal conductivity dielectrics, or a metal such as copper, titanium, or others. In some embodiments, as discussed further below, a hybrid bonded configuration may also be used. In some embodiments, enhanced thermal bonding layer 1001 has a thickness t6 in the range of 1 to 20 microns. In some embodiments, enhanced thermal bonding layer 1001 has a thickness t6 of not more than 20 microns, not more than 10 microns, or not more than 5 microns.

Handle die 1002 (or a structural member or element) is on the top of enhanced thermal bonding layer 1001. Handle die 1002 provides mechanical robustness as discussed herein and may include any materials or characteristics discussed herein with respect to handle dies 108, 201, 301, 403, 503, 600, 703, 803, 903. For example, enhanced thermal bonding layer 1001 may be deployed in any context discussed herein.

FIGS. 10B, 10C, 10D, and 10E illustrate cross-sectional side views of device structures as process operations are performed to fabricate microelectronic device 1000, arranged in accordance with some embodiments. FIG. 10B illustrates the formation of device structure 1010 such that multichip composite device 120 is formed on wafer 133 at multichip composite device operations 132, as discussed herein. FIG. 10C illustrates a device structure 1020 similar to device structures 1020 after a material removal operation 1021. As shown, material removal operation 1021 may expose surfaces of chiplets 104, 105 and provide a surface for application of a bonding layer. Material removal operation 1021 may include any suitable technique or techniques such as planarization operations, etch operations, or the like.

FIG. 10D illustrates a device structure 1030 similar to device structure 1020 after a deposition operation 1031 to provide enhanced thermal bonding layer 1001. As shown, in some embodiments, enhanced thermal bonding layer 1001 may be formed directly on or over multichip composite device 120. In other embodiments, enhanced thermal bonding layer 1001 is formed on a handle wafer that is bonded to multichip composite device 120. Enhanced thermal bonding layer 1001 may be formed using any suitable deposition techniques.

FIG. 10E illustrates a device structure 1040 similar to device structures 1030 after bonding operation 142 and dicing operation 143. A handle wafer and substrate wafer 133, including multichip composite device 120, are then bonded and subsequently diced. As discussed, enhanced thermal bonding layer 1001 may be formed on wafer 133 (as shown) or on the handle wafer or both. Bonding operation 142 may be performed using any suitable technique or techniques. In some embodiments, bonding operation 142 is performed at the wafer level and subsequent dicing operation 143 is performed.

With reference to FIG. 10A, subsequently, device structure 1040 may be packaged to form microelectronic device 1000. For example, device structure 1040 may be bump attached to package substrate 101 and underfill 102 may be provided. Microelectronic device 1000 may then be incorporated in any suitable form factor device discussed herein.

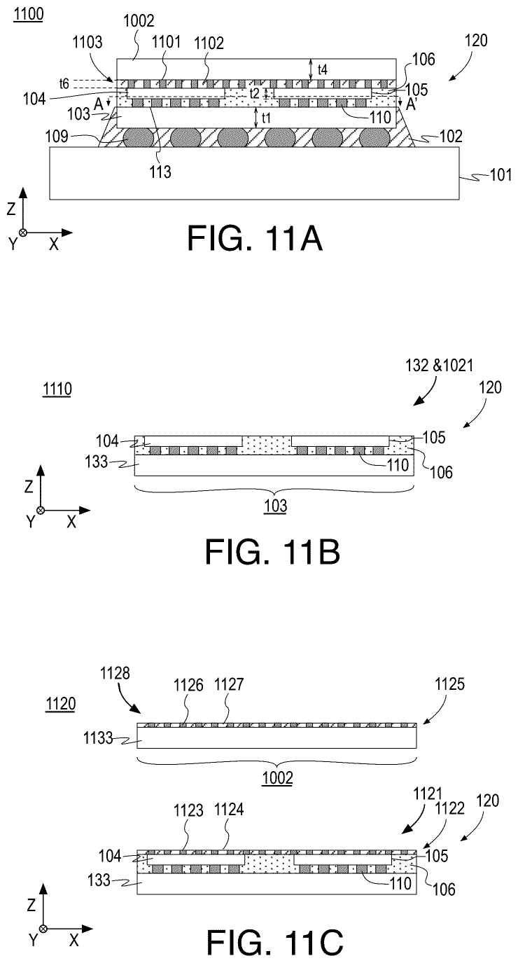

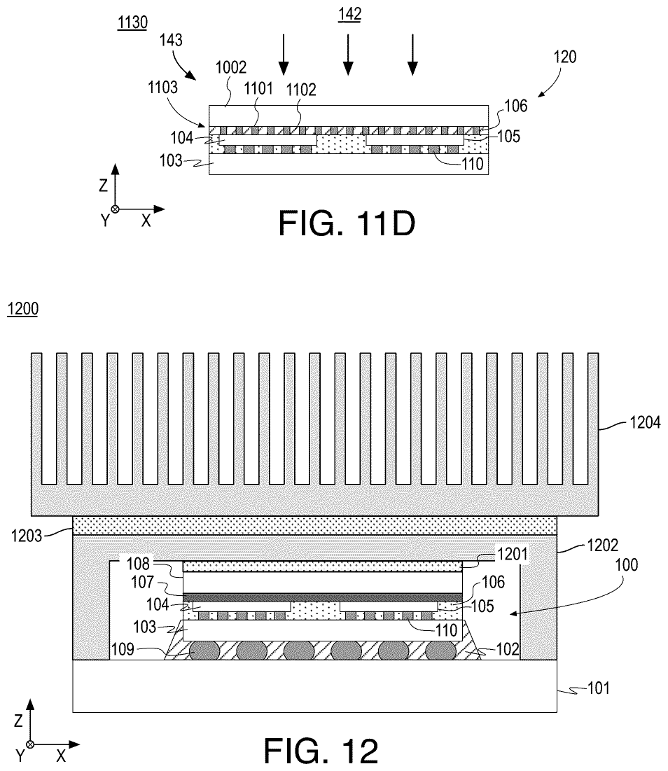

FIG. 11A illustrates a cross-sectional side view of a microelectronic device 1100 including an enhanced thermal hybrid bonding layer 1103, arranged in accordance with some embodiments. FIG. 1B illustrates a cross-sectional plan view taken at plane A-A′ in FIG. 11A. Microelectronic device 1100 includes any number of chiplets 104, 105 bonded to surface 113 of base die 103. Inorganic dielectric material 106 is filled in between chiplets 104, 105, on exposed portions of base die 103. In the example of FIG. 11A, inorganic dielectric material 106 is not over chiplets 104, 105.

As shown, enhanced thermal hybrid bonding layer enhanced thermal hybrid bonding layer 1001 is on top surfaces of chiplets 104 and on regions of inorganic dielectric material 106, as well as bonded to handle die. In the context of FIG. 11A, enhanced thermal hybrid bonding layer enhanced thermal hybrid bonding layer 1001 includes dielectric material 1102 and metallization 1101 interspersed therein. Dielectric material 1102 may include any suitable dielectric material such as silicon dioxide. Metallization 1101 may be any suitable metal such as copper, titanium, gold, or others with copper being particularly advantageous. Notably, inclusion of metallization 1101 provides for greater thermal conductivity of enhanced thermal hybrid bonding layer 1103.

In some embodiments, enhanced thermal hybrid bonding layer 1103 is formed using hybrid bonding techniques discussed herein. However, enhanced thermal hybrid bonding layer 1103 may be formed using any suitable technique or techniques Enhanced thermal hybrid bonding layer 1103 may have any thickness t6 discussed with respect to enhanced thermal bonding layer 1001. Furthermore, metallization 1101 may include, for example, through vias. Such through vias may have any characteristics such as varying sizes and/or densities as discussed with respect to FIG. 3B.

Handle die 1002 is on the top of enhanced thermal bonding layer 1001. Handle die 1002 provides mechanical robustness and may include any materials or characteristics discussed herein with respect to FIG. 10A. For example, enhanced thermal hybrid bonding layer 1103 may be deployed in any context discussed herein.

FIGS. 11B, 11C, and 11D illustrate cross-sectional side views of device structures as process operations are performed to fabricate microelectronic device 1100, arranged in accordance with some embodiments. FIG. 11B illustrates the formation of device structure 1110 such that multichip composite device 120 having recessed inorganic dielectric material 106 is formed on wafer 133 at multichip composite device operations 132 and material removal operation 1021, as discussed herein with respect to FIGS. 11B and 11C.

FIG. 11C illustrates a device structure 1120 similar to device structures 1110 after a hybrid bonding layer formation operations 1121, 1128. As shown, hybrid bonding layer formation operation 1121 forms a hybrid bonding layer 1122 on multichip composite device 120 such that hybrid bonding layer 1122 is on top surfaces of chiplets 10, 105 and inorganic dielectric material 106. Similarly, hybrid bonding layer formation operation 1128 forms a hybrid bonding layer 1125 on handle wafer 1133. Hybrid bonding layer 1122 includes metallization pads 1123 interspersed in dielectric material 1124. Hybrid bonding layer 1125 includes metallization pads 1126 interspersed in dielectric material 1127. In some embodiments, hybrid bonding layers 1122, 1125 have analogous patterns such that, during hybrid bonding, metallization pads 1123, 1126 are aligned and, in a similar manner, dielectric materials 1124, 1127 are aligned. Hybrid bonding layers 1122, 1125 may be formed using any suitable technique or techniques. In some embodiments, a dielectric layer is deposited and subsequently patterned using lithography and etch techniques. The metallization pads may then be formed in the opening using plating techniques followed by planarization techniques.

FIG. 11D illustrates a device structure 1130 similar to device structures 1120 after a bonding operation 142 and dicing operation 143. As shown, handle wafer 1133, including hybrid bonding layer 1125, and substrate wafer 133, including hybrid bonding layer 1122, are then bonded to form enhanced thermal hybrid bonding layer 1103. In some embodiments, bonding operation 142 is performed at the wafer level and subsequent dicing operation 143 is performed. Alternatively, in some embodiments, one or both of handle wafer 1133 and substrate wafer 133 are diced prior to bonding. For example, handle dies 1002 (including a portion of hybrid bonding layer 1125) may be diced from handle wafer 1133 and bonded to substrate wafer 133 (i.e., in a die to wafer manner). In embodiments where handle wafer 1133 and substrate wafer 133 are diced together, they share an area and vertically aligned edges as discussed with respect to FIG. 1B.

With reference to FIG. 11A, subsequently, device structure 1130 may be packaged to form microelectronic device 1100, which may then be incorporated in any suitable form factor device.

FIG. 12 illustrates an example microelectronic device assembly 1200 including a heat removal enhancement, in accordance with some embodiments. In the illustrative example of FIG. 12, microelectronic device 100 is represented. However, any microelectronic device discussed herein may be deployed in microelectronic device assembly 1200. As shown, microelectronic device assembly 1200 includes base die 103 attached to substrate 101 via interconnects 109, underfill 102. As discussed, chiplets 104, 105 are bonded to base die 103 by interconnects 110, and inorganic dielectric material 106 is provided adjacent chiplets 104, 105. In the context of FIG. 12, microelectronic device 100 also includes heat removal layer 107 and handle die 108; however other heat removal enhancement may be used. Microelectronic device assembly 1200 may include a power supply (not shown) coupled to one or more of base die 103, IC dies 104, 105, or other components of microelectronic device assembly 1200. The power supply may include a battery, voltage converter, power supply circuitry, or the like.

Microelectronic device assembly 1200 further includes a thermal interface material (TIM) 1201 disposed on a top surface of handle die 108. TIM 1201 may include any suitable thermal interface material and may be characterized as TIM 1. Integrated heat spreader 1202 having a surface on TIM 1201 extends over microelectronic device 100, and is mounted to substrate 101 or to a motherboard (not shown) on which substrate 101 is mounted. Microelectronic device assembly 1200 further includes TIM 1203 disposed on a top surface of integrated heat spreader 1202. TIM 1203 may include any suitable thermal interface material and may be characterized as TIM 2. TIM 1201 and TIM 1203 may be the same materials or they may be different. Heat sink 1204 (e.g., an exemplary heat dissipation device or thermal solution) is on TIM 1203 and dissipates heat generated by chiplets 104, 105 and base die 103. Although illustrated with respect to microelectronic device assembly 1200, the heat removal enhancement discussed herein may be deployed in any suitable architecture and form factor. For example, microelectronic device assembly 1200 may be used in desktop and server form factors. In other contexts, a heat solution such as a heat pipe or heat spreader may be mounted directly on TIM 1201. Such assemblies may be used in smaller form factor devices. Other heat dissipation devices may be used in concert with the heat removal enhancement structures discussed herein.

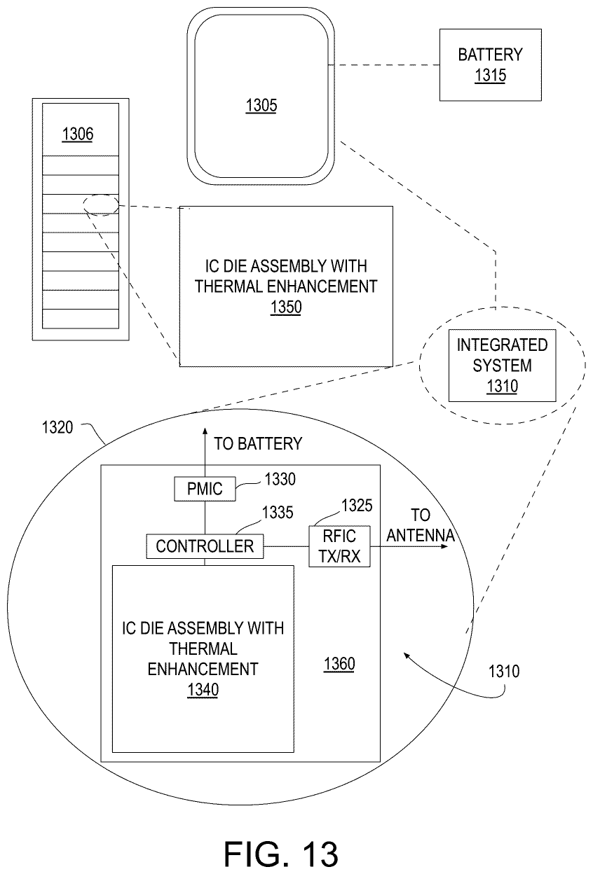

FIG. 13 illustrates exemplary systems employing an IC assembly including a heat removal enhancement, in accordance with some embodiments. The system may be a mobile computing platform 1305 and/or a data server machine 1306, for example. Either may employ a component assembly including at least heat removal enhancement as described elsewhere herein. Server machine 1306 may be any commercial server, for example including any number of high-performance computing platforms disposed within a rack and networked together for electronic data processing, which in the exemplary embodiment includes an IC die assembly 1350 with a heat removal enhancement as described elsewhere herein. Mobile computing platform 1305 may be any portable device configured for each of electronic data display, electronic data processing, wireless electronic data transmission, or the like. For example, mobile computing platform 1305 may be any of a tablet, a smart phone, a laptop computer, etc., and may include a display screen (e.g., a capacitive, inductive, resistive, or optical touchscreen), a chip-level or package-level integrated system 1310, and a battery 1315. Although illustrated with respect to mobile computing platform 1305, in other examples, chip-level or package-level integrated system 1310 and a battery 1315 may be implemented in a desktop computing platform, an automotive computing platform, an internet of things platform, or the like. As discussed below, in some examples, the disclosed systems may include a sub-system 1360 such as a system on a chip (SOC) or an integrated system of multiple ICs, which is illustrated with respect to mobile computing platform 1305.

Whether disposed within integrated system 1310 illustrated in expanded view 1320 or as a stand-alone packaged device within data server machine 1306, sub-system 1360 may include memory circuitry and/or processor circuitry 1340 (e.g., RAM, a microprocessor, a multi-core microprocessor, graphics processor, etc.), a power management integrated circuit (PMIC) 1330, a controller 1335, and a radio frequency integrated circuit (RFIC) 1325 (e.g., including a wideband RF transmitter and/or receiver (TX/RX)). As shown, one or more IC dice, such as memory circuitry and/or processor circuitry 1340 may be assembled and implemented such that one or more have a heat removal enhancement as described herein. In some embodiments, RFIC 1325 includes a digital baseband and an analog front end module further comprising a power amplifier on a transmit path and a low noise amplifier on a receive path). Functionally, PMIC 1330 may perform battery power regulation, DC-to-DC conversion, etc., and so has an input coupled to battery 1315, and an output providing a current supply to other functional modules. As further illustrated in FIG. 13, in the exemplary embodiment, RFIC 1325 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1340 may provide memory functionality for sub-system 1360, high level control, data processing and the like for sub-system 1360. In alternative implementations, each of the SOC modules may be integrated onto separate ICs coupled to a package substrate, interposer, or board.

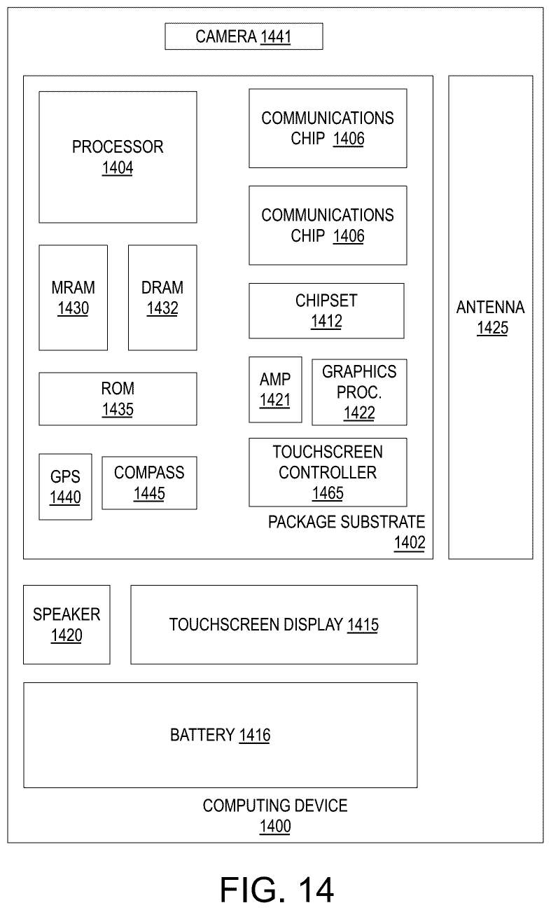

FIG. 14 is a functional block diagram of an electronic computing device 1400, in accordance with some embodiments. For example, device 1400 may, via any suitable component therein, employ heat removal enhancement (i.e., thermal enhancement) in accordance with any embodiments described elsewhere herein. Device 1400 further includes a motherboard or package substrate 1402 hosting a number of components, such as, but not limited to, a processor 1404 (e.g., an applications processor). Processor 1404 may be physically and/or electrically coupled to package substrate 1402. In some examples, processor 1404 is within an IC assembly that includes a heat removal enhancement as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1406 may also be physically and/or electrically coupled to the package substrate 1402. In further implementations, communication chips 1406 may be part of processor 1404. Depending on its applications, computing device 1400 may include other components that may or may not be physically and electrically coupled to package substrate 1402. These other components include, but are not limited to, volatile memory (e.g., DRAM 1432), non-volatile memory (e.g., ROM 1435), flash memory (e.g., NAND or NOR), magnetic memory (MRAM 1430), a graphics processor 1422, a digital signal processor, a crypto processor, a chipset 1412, an antenna 1425, touchscreen display 1415, touchscreen controller 1465, battery 1416, audio codec, video codec, power amplifier 1421, global positioning system (GPS) device 1440, compass 1445, accelerometer, gyroscope, speaker 1420, camera 1441, and mass storage device (such as hard disk drive, solid-state drive (SSD), compact disk (CD), digital versatile disk (DVD), and so forth, or the like.

Communication chips 1406 may enable wireless communications for the transfer of data to and from the computing device 1400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1406 may implement any of a number of wireless standards or protocols, including, but not limited to, those described elsewhere herein. As discussed, computing device 1400 may include a plurality of communication chips 1406. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, a microelectronic device comprises a multichip composite device comprising one or more chiplets connected to a surface of a base die, and an inorganic dielectric material laterally adjacent the one or more chiplets and over at least a portion of the base die, a structural member over the multichip composite device, and a layer on the structural member, and between the structural member and the multichip composite device, the layer having a thickness less than a thickness of the structural member, and the layer comprising a material having a thermal conductivity greater than a thermal conductivity of the structural member.

In one or more second embodiments, further to the first embodiments, the layer comprises one of diamond, copper, a compound of boron and nitrogen, a compound of boron and arsenic, or a compound of silicon and carbon.

In one or more third embodiments, further to the first or second embodiments, the layer is on the inorganic dielectric material.

In one or more fourth embodiments, further to the first through third embodiments, the structural member comprises crystalline silicon.

In one or more fifth embodiments, further to the first through fourth embodiments, the layer comprises crystalline diamond.

In one or more sixth embodiments, further to the first through fifth embodiments, the thickness of the layer is not more than 5 microns, the thickness of the structural member is not less than 50 microns, and at least one of the chiplets is hybrid bonded to the base die.

In one or more seventh embodiments, further to the first through sixth embodiments, the microelectronic device further comprises a second layer between the layer and the inorganic dielectric material, wherein the second layer is on the inorganic dielectric material and a surface of each of the one or more chiplets, the second layer comprising a compound of silicon and nitrogen or a compound of silicon and carbon.

In one or more eighth embodiments, further to the first through seventh embodiments, the microelectronic device further comprises a second layer between the layer and the inorganic dielectric material, wherein the second layer is on the inorganic dielectric material and a surface of each of the one or more chiplets, the second layer comprising a metal.

In one or more ninth embodiments, a microelectronic device comprises a multichip composite device comprising one or more chiplets connected to a surface of a base die, and an inorganic dielectric material laterally adjacent the one or more chiplets and over at least a portion of the base die and a structural member on the inorganic dielectric material and over the one or more chiplets, wherein the structural member has a thickness of not less than 25 microns, and comprises a material or a composite of materials, the material or at least one of the composite materials having a thermal conductivity of not less than 250 W/mK.

In one or more tenth embodiments, further to the ninth embodiments, the structural member comprises one of diamond, copper, boron and nitrogen, boron and arsenic, silicon and carbon, or aluminum and nitrogen.

In one or more eleventh embodiments, further to the ninth or tenth embodiments, the structural member comprises crystalline silicon and a plurality of through silicon vias (TSVs) comprising the material extending through the crystalline silicon.

In one or more twelfth embodiments, further to the ninth through eleventh embodiments, a plurality of first TSVs in a first region of the structural member has a first density and a plurality of second TSVs in a second region of the structural member has a second density less than the first density.

In one or more thirteenth embodiments, further to the ninth through twelfth embodiments, the inorganic dielectric material is between each of the one or more chiplets and the structural member, and at least one of the chiplets is hybrid bonded to the base die

In one or more fourteenth embodiments, further to the ninth through thirteenth embodiments, the microelectronic device further comprises a second layer between the structural member and the inorganic dielectric material, wherein the second layer is on the inorganic dielectric material and a surface of each of the one or more chiplets, the second layer comprising a compound of silicon and nitrogen or a compound of silicon and carbon.

In one or more fifteenth embodiments, further to the ninth through fourteenth embodiments, the microelectronic device further comprises a second layer between the structural member and the inorganic dielectric material, wherein the second layer is on the inorganic dielectric material and a surface of each of the one or more chiplets, the second layer comprising a metal.

In one or more sixteenth embodiments, a microelectronic device comprises a multichip composite device comprising one or more chiplets connected to a surface of a base die, and an inorganic dielectric material laterally adjacent the one or more chiplets and over at least a portion of the base die and a structural member over the multichip composite device, wherein the structural member comprises at least portions of a plurality of microchannels for flow of a cooling fluid therein, a first of the microchannels extending between a first of the one or more chiplets and a portion of the structural member to allow contact of the cooling fluid to the first of the one or more chiplets.

In one or more seventeenth embodiments, further to the sixteenth embodiments, the first of the microchannels extends laterally across a top surface of the first of the one or more chiplets to provide a substantially lateral flow of the cooling fluid across the top surface.

In one or more eighteenth embodiments, further to the sixteenth or seventeenth embodiments, the first of the microchannels further extends laterally across a top surface of a second of the chiplets.

In one or more nineteenth embodiments, further to the sixteenth through eighteenth embodiments, a port of the microchannels is above a top surface of the first of the one or more chiplets to provide a substantially perpendicular flow of the cooling fluid onto the top surface.

In one or more twentieth embodiments, further to the sixteenth through nineteenth embodiments, a fluid inlet port of the structural member extends into the microchannels at one of a center region or a peripheral region of the structural member, and a fluid outlet port of the structural member extends out of the microchannels at the other of the center region or the peripheral region.

In one or more twenty-first embodiments, further to the sixteenth through twentieth embodiments, the microchannels are within a plurality of silicon fin structures, the microelectronic device comprising a manifold structure over the fin structures, the manifold structure to receive the cooling fluid and direct the cooling fluid into the microchannels.

In one or more twenty-second embodiments, a system comprises a microelectronic device according to any of the preceding embodiments, and a power supply coupled to the microelectronic device and/or a thermal solution coupled to the microelectronic device.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A microelectronic device, comprising:
a multichip composite device comprising one or more chiplets connected to a surface of a base die, and an inorganic dielectric material laterally adjacent the one or more chiplets and over at least a portion of the base die;
a structural member over the multichip composite device; and
a layer on the structural member, and between the structural member and the multichip composite device, the layer having a thickness less than a thickness of the structural member, and the layer comprising a material having a thermal conductivity greater than a thermal conductivity of the structural member.

2. The microelectronic device of claim 1, wherein the layer comprises one of diamond, copper, a compound of boron and nitrogen, a compound of boron and arsenic, or a compound of silicon and carbon.

3. The microelectronic device of claim 2, wherein the layer is on the inorganic dielectric material.

4. The microelectronic device of claim 2, wherein the structural member comprises crystalline silicon.

5. The microelectronic device of claim 4, wherein the layer comprises crystalline diamond.

6. The microelectronic device of claim 1, wherein the thickness of the layer is not more than 5 microns, the thickness of the structural member is not less than 50 microns, and at least one of the chiplets is hybrid bonded to the base die.

7. The microelectronic device of claim 1, further comprising a second layer between the layer and the inorganic dielectric material, wherein the second layer is on the inorganic dielectric material and a surface of each of the one or more chiplets, the second layer comprising a compound of silicon and nitrogen or a compound of silicon and carbon.

8. The microelectronic device of claim 1, further comprising a second layer between the layer and the inorganic dielectric material, wherein the second layer is on the inorganic dielectric material and a surface of each of the one or more chiplets, the second layer comprising a metal.

9. A microelectronic device, comprising:
a multichip composite device comprising one or more chiplets connected to a surface of a base die, and an inorganic dielectric material laterally adjacent the one or more chiplets and over at least a portion of the base die; and
a structural member on the inorganic dielectric material and over the one or more chiplets,
wherein the structural member has a thickness of not less than 25 microns, and comprises a material or a composite of materials, the material or at least one of the composite materials having a thermal conductivity of not less than 250 W/mK.

10. The microelectronic device of claim 9, wherein the structural member comprises one of diamond, copper, boron and nitrogen, boron and arsenic, silicon and carbon, or aluminum and nitrogen.

11. The microelectronic device of claim 9, wherein the structural member comprises crystalline silicon and a plurality of through silicon vias (TSVs) comprising the material extending through the crystalline silicon.

12. The microelectronic device of claim 11, wherein a plurality of first TSVs in a first region of the structural member has a first density and a plurality of second TSVs in a second region of the structural member has a second density less than the first density.

13. The microelectronic device of claim 12, wherein the inorganic dielectric material is between each of the one or more chiplets and the structural member, and at least one of the chiplets is hybrid bonded to the base die.

14. The microelectronic device of claim 9, further comprising a second layer between the structural member and the inorganic dielectric material, wherein the second layer is on the inorganic dielectric material and a surface of each of the one or more chiplets, the second layer comprising a compound of silicon and nitrogen or a compound of silicon and carbon.

15. The microelectronic device of claim 9, further comprising a second layer between the structural member and the inorganic dielectric material, wherein the second layer is on the inorganic dielectric material and a surface of each of the one or more chiplets, the second layer comprising a metal.

16. A microelectronic device, comprising:
a multichip composite device comprising one or more chiplets connected to a surface of a base die, and an inorganic dielectric material laterally adjacent the one or more chiplets and over at least a portion of the base die; and
a structural member over the multichip composite device,
wherein the structural member comprises at least portions of a plurality of microchannels for flow of a cooling fluid therein, a first of the microchannels extending between a first of the one or more chiplets and a portion of the structural member to allow contact of the cooling fluid to the first of the one or more chiplets.

17. The microelectronic device of claim 16, wherein the first of the microchannels extends laterally across a top surface of the first of the one or more chiplets to provide a substantially lateral flow of the cooling fluid across the top surface.

18. The microelectronic device of claim 17, wherein the first of the microchannels further extends laterally across a top surface of a second of the chiplets.

19. The microelectronic device of claim 16, wherein a port of the microchannels is above a top surface of the first of the one or more chiplets to provide a substantially perpendicular flow of the cooling fluid onto the top surface.

20. The microelectronic device of claim 16, wherein a fluid inlet port of the structural member extends into the microchannels at one of a center region or a peripheral region of the structural member, and a fluid outlet port of the structural member extends out of the microchannels at the other of the center region or the peripheral region.

21. The microelectronic device of claim 16, wherein the microchannels are within a plurality of silicon fin structures, the microelectronic device comprising a manifold structure over the fin structures, the manifold structure to receive the cooling fluid and direct the cooling fluid into the microchannels.
